(19) United States
(12) Patent Application Publication
(10) Pub. No.: US 2009/0212660 A1
(43) Pub. Date: Aug. 27, 2009

(54) ULTRASONIC MOTOR AND METHOD FOR MANUFACTURING ULTRASONIC MOTOR

(75) Inventors: Masaya Iwaki, Wako (JP); Tomoko Iwaki, Wako (JP); Koji Akashi, Kyoto (JP); Norimichi Anazawa, Shinjuku (JP); Ken-ichi Kobayashi, Shinjuku (JP)

Correspondence Address: STAAS & HALSEY LLP, SUITE 700, 1201 NEW YORK AVENUE, N.W., WASHINGTON, DC, 20005, US

(73) Assignees: Holon Co., Ltd, Shinjuku (JP); Riken, Wako (JP); Kyocera Co. Ltd, Kyoto (JP)

(21) Appl. No.: 11/912,137

(22) PCT Filed: Apr. 20, 2006
(86) PCT No.: PCT/JP2006/308358

§ 371 Date: Jan. 14, 2009

(30) Foreign Application Priority Data
Apr. 21, 2005 (JP) 2005-124209

(51) Int. Cl. H02N 2/00; H01L 41/22

(52) U.S. Cl. 310/323.02; 29/25.35

(57) ABSTRACT

[Purpose] The present invention relates to an ultrasonic motor having a stator which includes a piezoelectric element for moving a rotor in a prescribed direction by applying a predetermined ultrasonic voltage thereto, and the rotor which is fixed to the stator by a frictional force, and a method for manufacturing an ultrasonic motor, and it has for its purpose to attain decrease of dust appearance by enhancement of a wear resistance, a different hardness, or the like in such a way that a contact part of at least either of a stator and a rotor which constitute the ultrasonic motor is irradiated with ions.

[Constitution] An ultrasonic motor characterized in that either or both of contact parts of a stator and a rotor is/are irradiated with ions, thereby to enhance a wear resistance of the contact part or parts.

### TECHNICAL FIELD

The present invention relates to an ultrasonic motor having a stator which includes a piezoelectric element for moving a rotor in a prescribed direction by applying a predetermined ultrasonic voltage thereto, and the rotor which is fixed to the stator by a frictional force, and a method for manufacturing an ultrasonic motor.

### BACKGROUND ART

In recent years, in the field of semiconductors, an ultrasonic motor is often utilized for the drive of a stage. This is considered to be based on the fact that, owing to its property, the ultrasonic motor has the two great features of being capable of realizing a microscopic drive of 1 nm, and a high position holding capability at the time of stop. The ultrasonic motor does not give rise to a backlash as is incurred in a stage drive mechanism of ball-screw thread.

The ultrasonic motor is configured of a stator which generates a vibration of predetermined phase, and a rotor which is moved by the vibration. The stator and the rotor are held at a predetermined position at a favorable precision by a frictional force.

### DISCLOSURE OF THE INVENTION

Problems that the Invention is to Solve

On account of the fundamental mechanism of an ultrasonic motor, there has been the problem that, when a rotor has been moved by bestowing a vibration of predetermined phase on a stator, frictional powder appears and intrudes between the rotor and the stator, so deterioration in a movement precision is incurred.

Besides, there has been the problem that the frictional powder having appeared adheres to an LSI mask or the like placed on a stage constituted by the ultrasonic motor and becomes a pollutant, which leads to the serious failure of the LSI mask.

### Means for Solving the Problems

In order to solve these problems, the present invention has for its object to attain the decrease of dust appearance by the enhancement of the wear resistance of a contact part, the different hardness of the contact part, or the like in such a way that the contact part of at least either of a stator and a rotor constituting an ultrasonic motor is irradiated with ions.

### ADVANTAGE OF THE INVENTION

The present invention can attain the decrease of dust appearance in such a way that the contact part of at least either of a stator and a rotor constituting an ultrasonic motor is irradiated with ions, whereby the wear resistance of the contact part of the stator or the rotor in the case of driving the ultrasonic motor is enhanced, and the hardnesses of both the stator and the rotor are made different.

### BEST MODE FOR CARRYING OUT THE INVENTION

The present invention permits the attainment of the decrease of dust appearance in such a way that the contact part of at least either of a stator and a rotor constituting an ultrasonic motor is irradiated with ions, whereby a wear resistance is enhanced, or a hardness is made different.

### EMBODIMENT 1

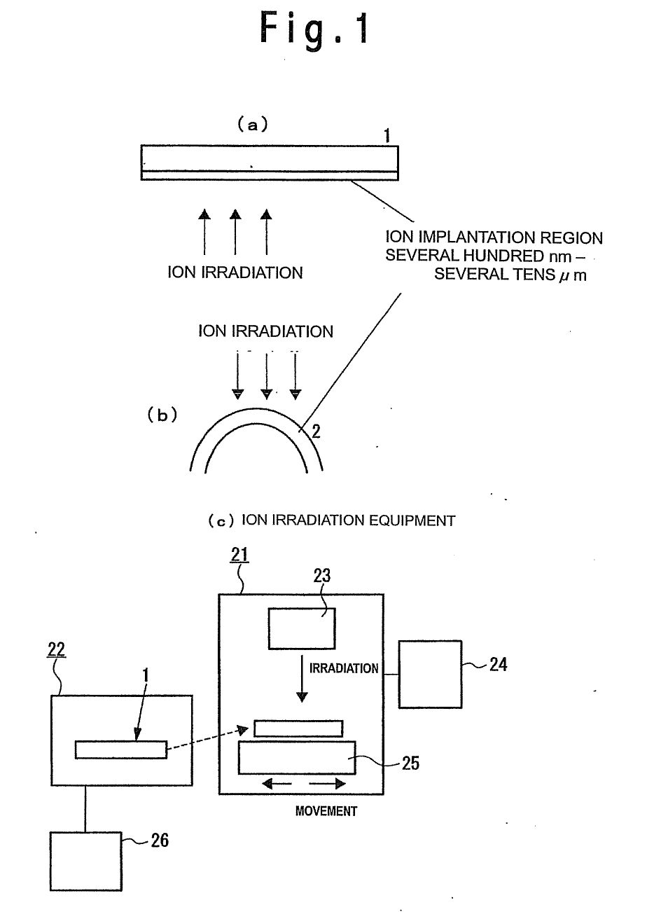

FIG. 1 shows an explanatory view of the present invention. (a) in FIG. 1 schematically shows an example of the ion irradiation of a rotor 1.

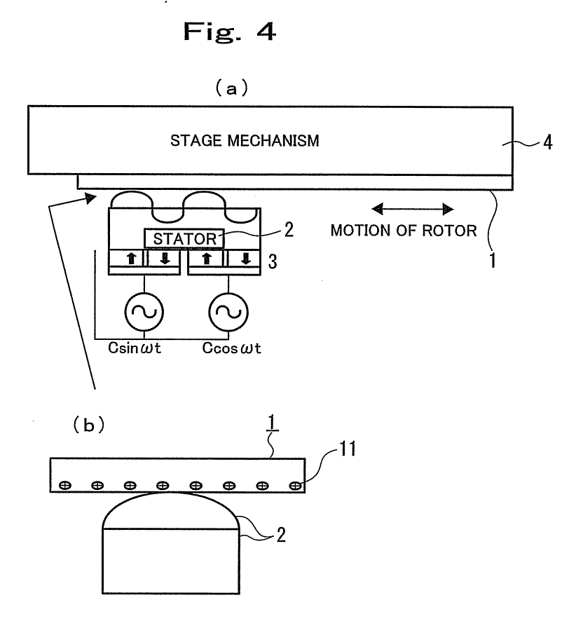

Referring to (a) in FIG. 1, the rotor 1 is such that the rotor 1 constituting an ultrasonic motor has been taken out. Here, it is the rotor 1 of the ultrasonic motor which drives a stage mechanism 4 at (a) in FIG. 4 to be stated later. The rotor 1 is formed of ceramics of alumina or the like, and that part of the rotor 1 which is to contact with a stator 2 (a part which is to be irradiated with ions) is machined to be very flat.

The rotor 1 and the stator 2 are formed of ceramics or the like, and especially, they are formed of the ceramics made of alumina (Al₂O₃) or AlTiC (Al₂O₃—TiC), whereby a wear resistance can be made higher. Here, the word “AlTiC” signifies ceramics which contain Al₂O₃ in a range of at least 20 weight-% to at most 80 weight-%, and TiC in a range of at least 20 weight-% to at most 80 weight-%.

At the illustrated part at which the rotor 1 contacts with the stator 2, a region of about several hundred nm to several tens pm is set as an ion implantation region (depthwise direction), and the ions are implanted into the region. The ions to be implanted may be any ions with which the wear resistance is enhanced, and they are the ions of at least one of nitrogen, carbon, boron, titanium, argon, chromium, nickel, copper, indium, silver and molybdenum, and any compound thereof. By way of example, the ions of nitrogen or argon were employed, whereby the wear resistance of the contact parts of the rotor 1 and the stator 2 could be enhanced.

Incidentally, at the contact parts of the rotor 1 and the stator 2, the surfaces of the rotor 1 and the stator 2 are subjected to Auger electron spectroscopy (AES), whereby the existence or nonexistence of the ion irradiations in depthwise directions from the surfaces can be verified.

(b) in FIG. 1 schematically shows an example of the ion irradiation of the stator 2.

Referring to (b) in FIG. 1, the stator 2 is such that the stator 2 constituting the ultrasonic motor has been taken out. Here, it is the stator 2 of the ultrasonic motor which drives the stage mechanism 4 at (a) in FIG. 4 to be stated later. The stator 2 is usually fabricated of alumina, and its part which is to contact with the rotor 1 (the part which is to be irradiated with ions) is machined to be very smooth. At the illustrated part at which the stator 2 contacts with the rotor 1, a region of about several hundred nm to several tens μm is set as an ion implantation region (depthwise direction), and the ions are implanted into the region. The ions to be implanted are the ions of at least one of, for example, nitrogen, carbon, boron, titanium, argon, chromium, nickel, copper, indium, silver and molybdenum, and any compound thereof, but as long as the wear resistance is enhanced, any other ions may well be employed without being restricted to the above ions.

(c) in FIG. 1 shows an example of an ion irradiation equipment.

Referring to (c) in FIG. 1, the ion irradiation equipment 21 is an equipment which implants the ions into the contact part of the rotor 1 at (a) in FIG. 1 or the stator 2 at (b) in FIG. 1, and it is configured of a preliminary evacuation chamber 22, an irradiation chamber, etc.

The preliminary evacuation chamber 22 is a room into which the rotor 1 or the stator 2 lying in the atmospheric air (within a clean room) is introduced, and which is then evacuated preliminarily. It is preliminarily evacuated from the atmospheric pressure down to a predetermined pressure by an oil-free pump. After the preliminary evacuation, the rotor 1 or the stator 2 is conveyed into a sample chamber being the body of the ion irradiation equipment 21, by a robot mechanism not shown, and it is fixed to a stage 25.

An ion source 23 generates the ions.

An ion pump 24 is a pump which evacuates the interior of the ion irradiation equipment 21 into a clean and high-vacuum state.

The stage 25 is a movement base which serves to fix the rotor 1, the stator 2 or the like for the ion irradiation, and to irradiate any desired place with the ions through scanning or the like.

The oil-free pump 26 is a pump which is free from oil, which evacuates air from the atmospheric pressure down to the predetermined pressure, and which is a molecular pump or the like.

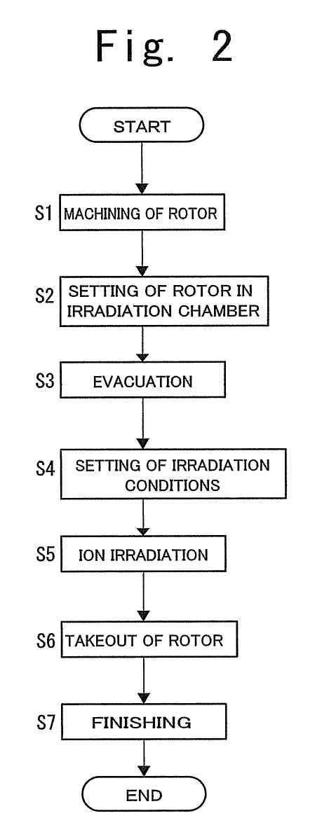

Under the above configuration, the rotor 1 at (a) in FIG. 1 or the stator 2 at (b) in FIG. 1 is introduced into the preliminary evacuation chamber 22, which is then preliminarily evacuated, and it is thereafter conveyed onto and fixed to the stage 25 within the sample chamber of the ion irradiation equipment 21. In addition, after the interior of the ion irradiation equipment 21 has been sufficiently evacuated by the ion pump 24, the ions emitted from the ion source 23 are accelerated under a predetermined high pressure, and the contact part of the rotor 1 at (a) in FIG. 1 or the stator 2 at (b) in FIG. 1 as is fixed on the stage 25 is implanted with the ions for a predetermined time period (as will be detailed in conjunction with the flow chart of FIG. 2). After the ion implantation has been ended, the rotor 1 or the stator 2 fixed on the stage 25 is conveyed into the preliminary evacuation chamber 22 and is taken out into the atmospheric air (into the clean room), whereupon the series of ion irradiation steps are completed.

Next, steps at the time when the rotor 1 at (a) in FIG. 1 or the stator 2 at (b) in FIG. 1 is irradiated with the ions by employing the ion irradiation equipment at (c) in FIG. 1 will be described in detail in a sequence in the flow chart of FIG. 2.

FIG. 2 shows a flow chart for explaining the ion irradiation in the invention.

Referring to FIG. 2, the step S1 machines a rotor. This machines, for example, the rotor 1 at (a) in FIG. 1, as the rotor 1 constituting the ultrasonic motor.

The step S2 sets the rotor in an irradiation chamber. This introduces the rotor 1 at (a) in FIG. 1 as has been machined at the step S1, into the preliminary evacuation chamber 22 constituting the ion irradiation equipment 21 at (c) in FIG. 1, and then preliminarily evacuates the interior of the preliminary evacuation chamber. Thereafter, this moves the rotor onto the stage 25 within the irradiation chamber on the body side, so as to fix and set the rotor.

The step S3 performs evacuation. After the rotor has been set on the stage 25 within the irradiation chamber at the step S2, the interior of the irradiation chamber is sufficiently evacuated by the ion pump 24.

The step S4 sets irradiation conditions. This sets, for example, the following as the irradiation conditions of the ion irradiation:
Irradiating ion acceleration voltage: Predetermined voltage of 1 keV—several hundred keV
Ion irradiation density: 10-10²⁰ ions/cm²
Ion species: Ions of nitrogen, carbon, boron, titanium, argon, chromium, nickel, copper, indium, silver or molybdenum, or any compound thereof
Irradiation method: Overall surface irradiation or scanning irradiation
Depth of implantation (computational value): about several hundred nm—several tens μm

The step S5 performs the ion irradiation. This performs an automatic control by a computer on the basis of the conditions set at the step S4 and irradiates the contact part of the rotor 1 or stator 2 fixed on the stage 25, with the ions.

The step S6 takes out the rotor 1. This takes out the rotor 1 having ended the ion irradiation at the step S5 (after the rotor 1 has been once put into the preliminary evacuation chamber from on the stage 25 at (c) in FIG. 1, air is introduced into the preliminary evacuation chamber so as to equalize the internal pressure of this chamber to the atmospheric pressure, and the rotor is taken out externally (into the clean room))

The step S7 finishes the rotor.

Owing to the above steps, the rotor 1 at (a) in FIG. 1 (or the stator 2 at (b) in FIG. 1) is set in the irradiation chamber and then irradiated with the ions, and it is taken out, whereby the ion irradiation is permitted for the contact part of the rotor 1 or stator 2 constituting the ultrasonic motor.

Here, an estimation test for wear resistances which depended upon the existence or nonexistence of the ion irradiations of the rotor 1 and the stator 2 in the invention was carried out. The rotor 1 and the stator 2 formed of alumina were prepared, and the surface of the stator was irradiated with ions under the following irradiation conditions:
Irradiating ion acceleration voltage: 80 keV
Ion irradiation density: 5×10¹⁶ ions/cm²
Ion species: Nitrogen
Irradiation method: Scanning irradiation
Depth of implantation (computational value): 63.4 μm

In addition, a drive test was carried out at a traveling distance of 10 km under the conditions that a rotational speed was 50 mm/s and that the pressing force of the stator 2 against the rotor 1 was 3 N. Thereafter, the arithmetic mean heights Ra of ten regions of 2 μm² in the surface of each of the samples of the rotor 1 and the stator 2 were measured in conformity with “JIS B 0601-2001”, and the average value thereof was calculated. As a result, in the case where the contact part of the stator 2 was irradiated with the ions, a wear quantity could be decreased down to, at most, about 45% as compared with a wear quantity in the case where neither of the rotor 1 and the stator 2 was irradiated with ions.

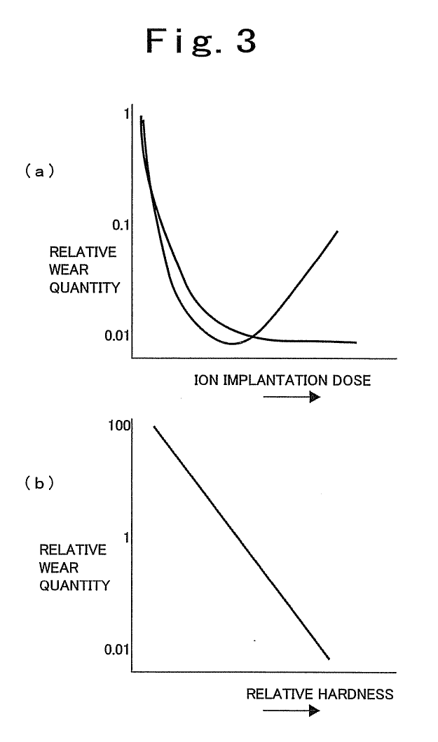

FIG. 3 shows an explanatory view of the invention.

(a) in FIG. 3 shows examples of the qualitative relational curves of a relative wear quantity versus an ion implantation dose. The axis of abscissas represents the ion implantation dose, while the axis of ordinates represents the relative wear quantity. In experiments, when the ion implantation dose was set to be small, medium and large, the relative wear quantity became gradually small as shown in the figure, in some cases, and it gradually became small and thereafter became large in the other cases. Accordingly, the optimum ion implantation dose with which the relative wear quantity is as small as possible may be experimentally found and determined. Incidentally, each “relative wear quantity” is a value at the time when the relative wear quantity in the case where the ion implantation dose is “0” at (a) in FIG. 3 is assumed to be “1”.

(b) in FIG. 3 shows an example of the qualitative relational curve of a relative hardness versus the relative wear quantity. The axis of abscissas represents the relative hardness, while the axis of ordinates represents the relative wear quantity. This is a qualitative representation obtained by measuring the relationship between the relative wear quantity at (a) in FIG. 3 and the relative hardness at that time as to the rotor 1.

Accordingly, there has been obtained the result that, as the relative hardness increases more, the relative wear quantity becomes smaller here.

Besides, the wear quantities of the stator 2 and the rotor 1 can be decreased in such a way that at least the contact parts of the stator 2 and the rotor 1 have been irradiated with the ions, whereby the hardness of the two is made different. Incidentally, the “hardness” termed here is the Vickers hardness (Hv), which can be measured in conformity with “JIS R 1601-1999”, and the “wear quantity” can be evaluated by measuring the arithmetic mean height (Ra) indicated in the above experimental example, in conformity with “JIS B 0601-2001”.

FIG. 4 shows an example of a stage in the invention. (a) in FIG. 4 schematically shows a situation where an ultrasonic motor is attached to a stage mechanism 4. When illustrated high-frequency voltages SIN ωt and COS ωt are applied to piezoelectric ceramics, the piezoelectric ceramics are lengthened, and when a stator 2 is fixed, a rotor 1 flatly held in contact by a frictional force can be moved in a rightward direction or a leftward direction (known movement method).

(b) in FIG. 4 shows a sectional view in which the rotor 1 and part of the stator 2 are taken out. Here, in the applicant's invention, a part at which the rotor 1 contacts with the stator 2 has been implanted with ions 11, and the wear resistance of the part has been enhanced, so that dust appearance from the contact part can be decreased.

### INDUSTRIAL APPLICABILITY

The present invention relates to an ultrasonic motor and a method for manufacturing an ultrasonic motor, in which the contact part of at least either of a stator and a rotor constituting the ultrasonic motor is irradiated with ions, thereby to attain the decrease of dust appearance by the enhancement of a wear resistance, a different hardness, or the like.

### BRIEF DESCRIPTION OF THE DRAWINGS

[FIG. 1] It is an explanatory view of the present invention.

[FIG. 2] It is a flow chart for explaining ion irradiation in the invention.

[FIG. 3] It is an explanatory view of the invention.

[FIG. 4] It shows an example of a stage in the invention

### DESCRIPTION OF REFERENCE NUMERALS

1: rotor,
2: stator,
3: piezoelectric ceramic,
4: stage mechanism,
11: ion,
21: ion irradiation equipment,
22: preliminary evacuation chamber,
23: ion source,
24: ion pump,
25: stage,
26: oil-free pump.

1. In an ultrasonic motor having a stator which includes a piezoelectric element for moving a rotor in a prescribed direction by applying a predetermined ultrasonic voltage thereto, and the rotor which is fixed to the stator by a frictional force;
an ultrasonic motor characterized in that either or both of contact parts of the stator and the rotor is/are irradiated with ions, thereby to enhance a wear resistance of the contact part or parts.

2. An ultrasonic motor as defined in claim 1, characterized in that the contact parts of the stator and the rotor are irradiated with the ions, thereby to make a hardness of the contact parts different and to enhance the wear resistance.

3. An ultrasonic motor as defined in claim 1, characterized in that, as the ion irradiation, the contact part or parts is/are irradiated with the ions of at least one of nitrogen, carbon, boron, titanium, argon, chromium, nickel, copper, indium, silver and molybdenum, or any compound thereof.

4. An ultrasonic motor as defined in claim 3, characterized in that the rotor and the stator are made of alumina or AlTiC (Al₂O₃—TiC).

5. In a method for manufacturing an ultrasonic motor which has a stator that includes a piezoelectric element for moving a rotor in a prescribed direction by applying a predetermined ultrasonic voltage thereto, and the rotor that is fixed to the stator by a frictional force;
a method for manufacturing an ultrasonic motor, characterized in that either or both of contact parts of the stator and the rotor is/are irradiated with ions, thereby to enhance a wear resistance of the contact part or parts.

6. An ultrasonic motor as defined in claim 1, characterized in that, as the ion irradiation, the contact part or parts is/are irradiated with the ions of at least one of nitrogen, carbon, boron, titanium, argon, chromium, nickel, copper, indium, silver and molybdenum, or any compound thereof.

7. An ultrasonic motor as defined in claim 6, characterized in that the rotor and the stator are made of alumina or AlTiC (Al₂O₃—TiC).

8. An ultrasonic motor as defined in claim 2, characterized in that the rotor and the stator are made of alumina or AlTiC (Al₂O₃—TiC).

9. An ultrasonic motor as defined in claim 1, characterized in that the rotor and the stator are made of alumina or AlTiC (Al₂O₃—TiC).
